(19) United States
(12) Patent Application Publication
(10) Pub. No.: US 2025/0111121 A1
(43) Pub. Date: Apr. 3, 2025

(54) RUNTIME OPTIMIZATION OF ACTIVE INTERPOSER DIES FROM DIFFERENCE PROCESS BINS

(71) Applicant: Advanced Micro Devices, Inc., Santa Clara, CA (US)

(72) Inventors: Ashish Jain, Austin, TX (US); Lakshminarayana Pappu, Folsom, CA (US)

(21) Appl. No.: 18/478,469

(22) Filed: Sep. 29, 2023

(51) Int. Cl. G06F 30/373

(52) U.S. Cl. CPC G06F 30/373

(57) ABSTRACT

An apparatus and method for efficiently managing performance and power consumption among replicated functional blocks of an integrated circuit despite different circuit behavior amongst the functional blocks due to manufacturing variations. An integrated circuit includes multiple replicated functional blocks, each being a semiconductor die with a corresponding communication fabric for routing packets. A second functional block placed between a first functional block and a third functional block routes packets to destinations from at least the first and the third functional blocks, and provides higher performance than the first and the third functional blocks due to semiconductor manufacturing variations. A power manager assigns a single power supply voltage to the replicated functional blocks, and assigns a target clock frequency to the first and the third functional blocks. The power manager assigns another clock frequency greater than the target clock frequency to the second functional block.

### BACKGROUND

### Description of the Relevant Art

Generally speaking, semiconductor fabrication includes multiple complex steps to produce multiple semiconductor dies on a wafer with each semiconductor die providing the same functionality. These steps can cause one or more semiconductor dies on the wafer to have different circuit behavior than other semiconductor dies on the same wafer or another wafer despite each of the semiconductor dies providing the same functionality. These differences in behavior result from manufacturing variations across semiconductor dies that inadvertently cause different widths of metal gates and metal traces, different doping levels of source and drain regions, different thicknesses of insulating oxide layers, different thicknesses of metal layers, and so on. These manufacturing variations also affect the threshold voltages of transistors. When the semiconductor package utilizes multiple copies of a same semiconductor die and even when the multiple copies receive a same workload, the behavior of the resulting semiconductor chip can vary depending on which bins the semiconductor dies were selected to be placed in the semiconductor chip.

In view of the above, efficient methods and apparatuses for managing performance among replicated functional blocks of an integrated circuit despite different circuit behavior amongst the functional blocks due to manufacturing variations are desired.

### BRIEF DESCRIPTION OF THE DRAWINGS

FIG. 1 is a generalized block diagram of an integrated circuit that manages performance and power consumption among replicated functional blocks, such as semiconductor dies, of an integrated circuit despite different circuit behavior of the functional blocks due to manufacturing variations.

FIG. 2 is a generalized block diagram of an integrated circuit that manages performance and power consumption among replicated functional blocks, such as semiconductor dies, of an integrated circuit despite different circuit behavior of the functional blocks due to manufacturing variations.

FIG. 3 is a generalized block diagram of operating parameters selection circuitry that manages performance and power consumption among replicated functional blocks, such as semiconductor dies, of an integrated circuit despite different circuit behavior of the functional blocks due to manufacturing variations.

FIG. 4 is a generalized diagram of a method for efficiently managing performance and power consumption among replicated functional blocks, such as semiconductor dies, of an integrated circuit despite different circuit behavior of the functional blocks due to manufacturing variations.

FIG. 5 is a generalized diagram of a method for efficiently managing performance and power consumption among replicated functional blocks, such as semiconductor dies, of an integrated circuit despite different circuit behavior of the functional blocks due to manufacturing variations.

FIG. 6 is a generalized block diagram of an integrated circuit that manages performance and power consumption among replicated functional blocks, such as semiconductor dies, of an integrated circuit despite different circuit behavior of the functional blocks due to manufacturing variations.

FIG. 7 is a generalized block diagram of a computing system that manages performance and power consumption among replicated functional blocks, such as semiconductor dies, of an integrated circuit despite different circuit behavior of the functional blocks due to manufacturing variations.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

Apparatuses and methods efficiently managing performance and power consumption among replicated functional blocks of an integrated circuit despite different circuit behavior amongst the functional blocks due to manufacturing variations are contemplated. In various implementations, an integrated circuit includes multiple replicated functional blocks, each being a semiconductor die with an instantiated copy of particular integrated circuitry. In an implementation, each of the replicated functional blocks is an active interposer die of a three-dimensional (3D) stacked integrated circuit (IC), and each of the active interposer dies includes a corresponding communication fabric. For example, the active devices in the active interposer dies implement queues for storing memory access requests, memory access responses, messages, commands, and so forth. These active devices also implement network switches (or routers) of the communication fabric that includes arbitration circuitry, signal drivers, interface circuitry, configuration registers, and so forth. In the 3D stacked IC, a corresponding computation die is placed above each of the active interposer dies. In some implementations, the active devices in the active interposer dies also provide a particular hierarchy of a multi-hierarchical cache memory subsystem, such as a corresponding level three (L3) cache, accessed by at least a processor of a corresponding computation die.

In various implementations, the integrated circuit includes at least three replicated functional blocks. A first functional block manages memory access and communication packets corresponding to a first computation die. Similarly, a second functional block and a third functional block manage memory access and communication packets corresponding to a second computation die and a third computation die, respectively. The second functional block is placed in the integrated circuit between the first functional block and the third functional block. Therefore, the second functional block of the replicated functional blocks is responsible for routing packets between sources and destinations with the sources and the destinations including one or more processors of the second computation die, the first functional block, and the third functional block of the replicated functional blocks.

The second functional block handles packet routing that is absent from the first functional block and the third functional block. For example, the first functional block is not used for routing packets between sources and destinations with the sources and destinations including the third functional block (or a processor of the corresponding third computation die) and the second functional block (or a processor of the corresponding second computation die). Similarly, the third functional block is not used for routing packets between sources and destinations with the sources and destinations including the first functional block (or a processor of the corresponding first computation die) and the second functional block (or a processor of the corresponding second computation die). Therefore, the second functional block has higher packet routing congestion in its communication fabric compared to the communication fabrics of the first functional block and the third functional block.

In various implementations, during testing of dies after semiconducting manufacturing of silicon wafers, it is determined that the second functional block belongs to a higher performance bin than bins of the first functional block and the third functional block due to semiconductor manufacturing variations. Therefore, the second functional block is capable of providing a maximum clock frequency that is higher than maximum clock frequencies provided by the first functional block and the third functional block. During operation of an integrated circuit, circuitry of a power manager determines a target clock frequency for the replicated functional blocks, and selects a single power supply voltage to assign to the replicated functional blocks. In some implementations, each of the first functional block, the second functional block, and the third functional block share a same power rail. The power manager updates operating parameters of the replicated functional blocks to include the single power supply voltage for each of the replicated functional blocks. The power manager assigns the target clock frequency to the first functional block and the third functional block, but assigns an operating clock frequency to the second functional block that is greater than the target clock frequency. Therefore, the second functional block provides higher performance to alleviate the packet routing congestion in its communication fabric without significantly increasing the power consumption of the integrated circuit.

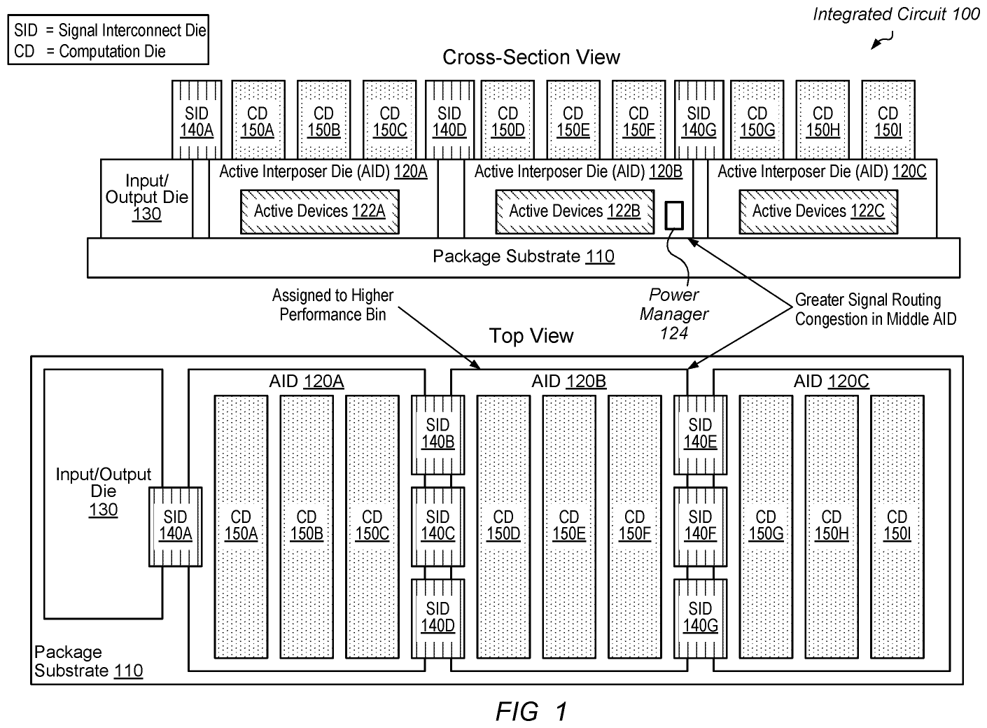

In some implementations, the functional blocks are chiplets. As used herein, a “chiplet” is also referred to as a “functional block,” or an “intellectual property block” (or IP block). However, a “chiplet” is a semiconductor die (or die) fabricated separately from other dies, and then interconnected with these other dies in a single integrated circuit in the multi-chip module (MCM). A chiplet is a type of functional block. However, a functional block is a term that also describes blocks fabricated with other functional blocks on a larger semiconductor die such as a system-on-a-chip (SOC). Therefore, a chiplet is a subset of “functional blocks” in a semiconductor chip. The scheduler assigns work blocks to the chiplets based on whether a chiplet is assigned to a higher performance bin and whether a workload of a work block is a computation intensive workload. Further details of these techniques for efficiently managing performance and power consumption among replicated functional blocks of an integrated circuit despite different circuit behavior amongst the functional blocks due to manufacturing variations are provided in the following description of FIGS. 1-5.

Referring to FIG. 1, a generalized block diagram is shown of an implementation of an integrated circuit 100. In various implementations, the integrated circuit 100 is a three-dimensional (3D) stacked integrated circuit (IC). A cross-section view of the integrated circuit 100 is provided at the top of FIG. 1, and a top view of the integrated circuit 100 is provided at the bottom of FIG. 1. The integrated circuit 100 includes a package substrate 110 with multiple semiconductor dies (or dies) integrated vertically on top of it. The multiple dies include the active interpose dies (AID) 120A-120C on top of the package substrate 110. Each of the computation dies (CD) 150A to CD 150I is on top of a corresponding one of the active interpose dies (AIDs) 120A-120C. Additionally, each of the signal interconnect dies 140A-140G is on top of a corresponding one of the active interpose dies (AIDs) 120A-120C.

In various implementations, three-dimensional (3D) packaging is used within a computing system. This type of packaging is referred to as a System in Package (SiP). A SiP includes one or more three-dimensional integrated circuits (3D ICs) that includes two or more layers of active electronic components integrated both vertically and/or horizontally into a single circuit. Die-stacking technology is a fabrication process that enables the physical stacking of multiple separate semiconductor dies together in a same package with high-bandwidth and low-latency interconnects. In some implementations, the dies are stacked side by side on a silicon interposer, such as the active interpose dies 120A-120C, and/or vertically directly on top of each other.

The package substrate 110 is a part of the semiconductor chip package that provides mechanical base support as well as provides an electrical interface for the signal interconnects for both dies within the integrated circuit 100 and external devices on a printed circuit board. The packaging substrate 110 uses ceramic materials such as alumina, aluminum nitride, and silicon carbide. The package substrate 110 utilizes controlled collapse chip connection (C4) interconnections (not shown), which is also referred to as flip-chip interconnection. For example, C4 bumps are connected to vertical through silicon vias (TSVs) formed in the package substrate 110 that has connections to the printed circuit board using bump pads.

Groups of TSVs forming through silicon buses are used as interconnects between a base die, one or more additional integrated circuits, and routing on a printed circuit board (PCB) such as a motherboard or a card. Through silicon buses are used as a vertical electrical connection traversing through a silicon wafer and provide alternative interconnect to wire-bond and flip chips. The size and density of the vertical interconnects, such as TSVs and through silicon buses, which can tunnel between the different device layers varies based on the underlying technology used to fabricate the 3D ICs. The demand for SiPs and more signal interconnects between the integrated circuits and the printed circuit board (PCB) also increases the demand for package substrates and interposers.

In some implementations, the integrated circuit 100 includes redistribution layers between the package substrate 110 and the active interposer dies 120A-120C. The redistribution layers include signal routes using multiple metal layers and vias that provide physical connection between adjacent metal layers of the redistribution layers. Dielectric material, such as silicon dioxide, is also used between adjacent metal layers and within metal layers to provide electrical insulation between signal routes. Generally speaking, an interposer is an intermediate layer between the computation dies 150A-150I and either flip chip bumps or other interconnects and the package substrate 110. An interposer can be manufactured using silicon or organic materials.

The active interposer dies 120A-120C can provide multiple, large channels for signal routes, which reduces the power consumed to drive signals, minimizes the resistance and capacitance effects on signal routes, and reduces the distances of signal interconnects between the signal interconnect dies 140A-140E and the computation dies 150A-150I. For example, the active interposer dies 120A-120C provide the electrical interface for the signal interconnects between the one or more dies assembled on it (die-to-die interconnects), such as the signal interconnect dies 140A-140E and the computation dies 150A-150I, and the package substrate 110 (die-to-package interconnects). Similar to the package substrate 110 and any redistribution layers, the active interposer dies 120A-120C also use TSVs and through silicon buses.

Each of the computation dies 150A-150I include circuitry for processing data such as one or more processor cores. These one or more processor cores provide the functionality of one of a central processing unit (CPU) with a general-purpose microarchitecture, a graphics processing unit (GPU) with a highly parallel data microarchitecture, an accelerated processing unit (APU), a digital signal processor (DSP), a field programmable gate array (FPGA), an application specific integrated circuit (ASIC), or other. In some implementations, each of the computation dies 150A-150I has a same microarchitecture. However, in various other implementations, at least one of the computation dies 150A-150I has a microarchitecture distinct from other dies of the computation dies 150A-150I. In an implementation, one or more of the computation dies 150A-150I provides the functionality of a shader circuit within a shader array of a GPU. The computation dies 150A-150I are used in a computing system that communicates with other chips on a printed circuit board within a laptop computer, a smart phone, a tablet computer, a desktop computer, a server; or other.

Each of the signal interconnect dies (SIDs) 140A-140E includes a relatively small semiconductor die that provides signal interconnections between two other separate semiconductor dies within a semiconductor package. Therefore, the signal interconnect dies 140A-140E provide more input/output signal communication within the semiconductor package, which reduces the memory bandwidth bottleneck in the integrated circuit 100. As shown, the signal interconnect die 140A provides input/output signal communication between the computation dies 150A-150C and the input/output die 130, which provides access to external devices such as an external memory, an external multimedia circuit, one or more display controllers for one or more video display devices, or other. The signal interconnect dies 140B, 140C and 140D provide input/output signal communication between the computation dies 150A-150C and the computation dies 150D-150F. The signal interconnect dies 140E, 140F and 140G provide input/output signal communication between the computation dies 150D-150F and the computation dies 150G-150I.

Each of the active interposer dies 120A-120C includes signal interconnects, embedded passive components, such as inductors and decoupling capacitors, voltage regulators, and active devices (or transistors). As shown, the active interposer die 120A includes the active devices 122A, the active interposer die 120B includes the active devices 122B, and the active interposer die 120C includes the active devices 122C. As used herein, a “transistor” is also referred to as a “semiconductor device,” an “active device,” or a “device.” The integrated circuit 100 uses p-type metal oxide semiconductor (PMOS) field effect transistors FETS (or pfets) in addition to n-type metal oxide semiconductor (NMOS) FETS (or nfets). In some implementations, the devices (or transistors) in the integrated circuit 100 are planar devices. In other implementations, the devices (or transistors) in the integrated circuit 100 are non-planar devices. Examples of non-planar transistors are tri-gate transistors, fin field effect transistors (FIN FETs), and gate all around (GAA) transistors.

Each of the active devices 122A-122C of the active interposer dies 120A-120C includes circuitry that supports a memory controller and an input/output (I/O) communication fabric between the computation dies 150A-150I and the memory controller. The active devices 122A-122C in the active interposer dies 120A-120C implement queues for storing memory access requests, memory access responses, messages, snoop requests, snoop responses, packets that include a variety of types of requests, responses, commands, and so forth. The active devices 122A-122C in the active interposer dies 120A-120C also implement network switches (or routers) of the communication fabric that includes arbitration circuitry, signal drivers, interface circuitry, clock generating circuitry, configuration registers, and so forth.

Additionally, the active devices 122A-122C implement a particular hierarchy of a multi-hierarchical cache memory subsystem such as a corresponding level three (L3) cache. For example, the active interposer die 120A includes a level three (L3) cache that can be accessed by any of the computation dies 150A-150I. Similarly, each of the active interposer dies 120B-120C includes a corresponding L3 cache that can be accessed by any of the computation dies 150A-150I. In other implementations, the hierarchical level of the cache implemented in the active interposer dies 120B-120C is different from an L3 cache.

The integrated circuit 100 provides high density and heterogeneous semiconductor technology integration in a module or a package. Minimum system board area is used to support the integrated circuit 100, such as an area occupied by the package substrate 110 on a printed circuit board. The integrated circuit 100 is used in a system-in-package (SiP), a multi-chip module (MCM), or other type of packaged product. Although a particular number of components are shown in the illustrated implementation of the integrated circuit 100, in other implementations, another number of components are used, additional components not shown are used, and some components being shown are not used. The choices for the number and types of components being used are based on design requirements. It is noted that although the terms “left,” “right,” “horizontal,” “vertical,” “row,” “column,” “top,” and “bottom” are used to describe the integrated circuit 100, the meaning of the terms can change as the integrated circuit 100 is rotated, flipped, or otherwise viewed from a different perspective.

In some implementations, each of the computation dies 150A-150I and the signal interconnect dies 140A-140E is a chiplet. A “chiplet” is also referred to as a “functional block,” or an “intellectual property block” (or IP block). However, a “chiplet” is a semiconductor die (or die) fabricated separately from other dies, and then interconnected with these other dies in a single integrated circuit in the MCM. A chiplet is a type of functional block. However, a functional block is a term that also describes blocks fabricated with other functional blocks on a larger semiconductor die such as the SoC. Therefore, a chiplet is a subset of “functional blocks” in a semiconductor chip. The computation dies 150A-150I and the signal interconnect dies 140A-140E can also be referred to as functional blocks 150A-150I and 140A-140E.

As described earlier, each of the computation dies 150G-150I generates memory access requests, snoop requests, and other commands that target data stored in a cache located in another active interposer die than a corresponding local one of the active interposer dies 120A-120C. For example, the computation die 150H can generate a memory access request targeting data stored in an L3 cache located in the active interposer die 120A, rather than in a L3 cache located in the active interposer die 120C. Therefore, the communication fabric of the active interposer die 120B becomes congested as requests, responses, commands, and other types of packets traverse through this communication fabric from multiple sources. These multiple sources include the computation dies 150D-150F, the active interposer die 120A, and the active interposer die 120C.

In various implementations, at least the active interposer dies 120A-120C share a same power rail although the active interposer dies 120A-120C can utilize a separate clock signal. To increase the transfer of requests, responses, commands, and other types of packets through the communication fabric of the active interposer die 120B, each of the operating power supply voltage and the operating clock frequencies of the active interposer dies 120A-120C can be increased. However, this approach increases power consumption. In contrast, a higher operating clock frequency can be achieved by the active interposer die 120B without raising the operating power supply voltage and operating clock frequencies of the active interposer dies 120A and 120C when the active interposer die 120B is from a higher performance bin.

One or more of the functional blocks of the integrated circuit 100, such as the active interposer dies 120A-120C, belong in a different performance category or bin than other functional blocks due to semiconductor manufacturing variations. The active interposer dies 120A-120C provide the same functionality, but provide different circuit behavior due to manufacturing variations between them. An example of the different circuit behavior is transistor speed, which can affect the supported maximum operating clock frequency. In various implementations, the active interposer die 120B is from a higher performance bin compared with the active interposer dies 120A and 120C, which are from lower performance bins. In some implementations, each of the active interposer dies 120A-120C store a corresponding semiconductor die characterization table (or table). This table includes information that specifies a performance category or bin of the corresponding one of the active interposer dies 120A-120C. In an implementation, the table includes information that specifies a maximum operating clock frequency for the corresponding one of the active interposer dies 120A-120C. In some implementations, the table stores data of a dynamic (adaptive) voltage and frequency scaling curve for the corresponding one of the active interposer dies 120A-120C.

In various implementations, the table that stores the dynamic (adaptive) voltage and frequency scaling curve data is implemented with a fuse array, or a fuse read-only memory (ROM). The fuse ROM utilizes electronic fuses (Efuses) that can be programmed during die characterization in a testing environment, but a continued ability to program is not available in the field. Typically, a fuse is blown at manufacturing time, and its state generally cannot be changed once blown. Fuses can be used to encode a variety of types of information such as the dynamic (adaptive) voltage and frequency scaling curve data, manufacturing information, such as a chip serial number and identification of a performance bin, the supported maximum operating clock frequency, and other information. Besides Efuses, it is possible and contemplated that the fuse ROM uses other fuse technologies such as laser and soft fuses.

The hardware, such as circuitry, of a scheduler (not shown) assigns instructions to the computation dies 150A-150I based on a current workload. The circuitry of the power manager 124 assigns a target power supply voltage on the power rail shared by the active interposer dies 120A-120C. The power manager 124 also assigns a target operating clock frequency to the active interposer die 120A and the active interposer die 120C. Additionally, the power manager 124 assigns a given operating clock frequency that is greater than the target operating clock frequency to the active interposer die 120B. Therefore, the active interposer die 120B provides higher performance than each of the active interposer dies 120A and 120C to alleviate the packet routing congestions in its communication fabric without significantly increasing the power consumption of the integrated circuit 100. It is noted that although the power manager 124 is shown being located in the active interposer die 120B, in other implementations, the power manager 124 is located elsewhere.

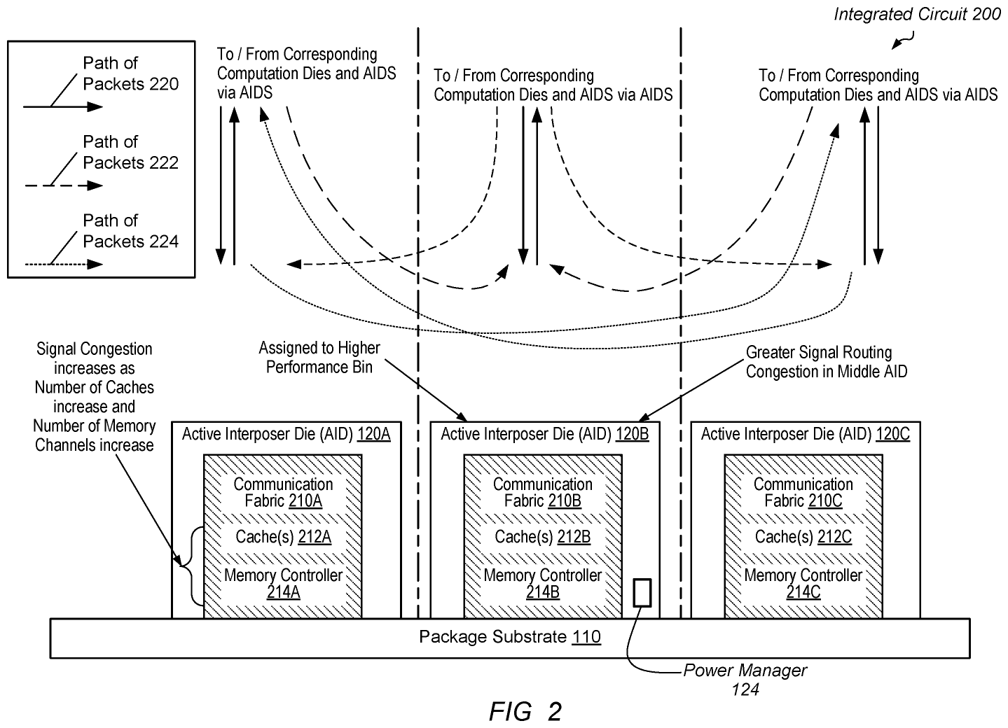

Turning now to FIG. 2, a generalized block diagram is shown of an implementation of an integrated circuit 200. In various implementations, the integrated circuit 200 is a three-dimensional (3D) stacked integrated circuit (IC). Circuitry and blocks described earlier are numbered identically. The computation dies that are placed on top of the active interposer dies (AIDs) 120A-120C and the signal interconnect dies that provide signal interconnections between two other separate semiconductor dies are not shown for ease of illustration. As described earlier, each of the active interposer dies 120A-120C includes active devices used to implement the functionality of various components. In various implementations, the components of the active interposer dies 120B-120C are instantiated copies of the components of the active interposer die 120A. In some implementations, the active interposer die 120A includes at least the communication fabric 210A, the cache(s) 212A, and the memory controller 214A. Similarly, the active interposer die 120B includes at least the communication fabric 210B, the cache(s) 212B, and the memory controller 214B, and the active interposer die 120C includes at least the communication fabric 210C, the cache(s) 212C, and the memory controller 214C. For the communication fabric 210A, the active devices of the active interposer die 120A implement queues for storing memory access requests, memory access responses, messages, commands, and so forth. These active devices also implement network switches (or routers) of the communication fabric 210A that includes arbitration circuitry, signal drivers, interface circuitry, configuration registers, and so forth.

The cache(s) 212A include one or more caches of a cache memory subsystem. In some implementations, the cache(s) 212A include a last-level cache of the cache memory subsystem. In an implementation, the cache(s) 212A include one last-level cache for each of the computation dies placed on top of the active interposer die 120A. In another implementation, the cache(s) 212A include one last-level cache for each memory channel supported by the memory controller 214A in the active interposer die 120A. In some implementations, one or more of the cache(s) 212A store only data of a particular type such as video frame data or rendered video frame data to be accessed by a display controller of the input/output die 130 (not shown here for ease of illustration). The memory controller 214A includes circuitry that transfers data, via one or more communication channels, with one of a system memory, a local memory, or another type of off-chip memory. The circuitry of the memory controller 214A includes one or more queues for storing requests, responses, and messages, and the circuitry builds packets for transmission to circuitry that disassembles packets upon reception.

The circuitry of the memory controller 214A also supports one of a variety of communication protocols used by a communication channel that transfers data with off-chip memory. In various implementations, the communication channel 172 is a point-to-point communication channel. A point-to-point communication channel is a dedicated communication channel between a single source and a single destination. Therefore, the point-to-point communication channel transfers data only between the single source and the single destination. The off-chip memory is one of a variety of types of synchronous random-access memory (SRAM), or one of a variety of types of synchronous dynamic random-access memory (SDRAM). The off-chip memory is provided in a separate semiconductor package on the motherboard. In various implementations, a particular memory channel is provided for each memory device such as a dual in-line memory module (DIMM) or other. In some implementations, each memory channel supports a multi-channel configuration to increase the data transfer rate. In an implementation, the memory controller 214A, the communication channel, and the off-chip memory support one of a variety of types of a Double Data Rate (DDR) communication protocol, one of a variety of types of a Low-Power Double Data Rate (LPDDR) communication protocol, one of a variety of types of a Graphics Double Data Rate (GDDR) communication protocol, and so forth.

Multiple paths of packets 220-224 are shown illustrating the transfer of packets between computation dies via one or more of the active interposer dies 120A-120C. The path of packets 220 (or path 220) illustrates a path that packets traverse when the packets have a source and a destination that includes a computation die and its corresponding one of the active interposer dies 120A-120C. For example, the path 220 exists for the active interposer die 120B and a computation die (not shown) placed on top of the active interposer die 120B. The path of packets 222 (or path 222) illustrates a path that packets traverse when the packets have a source and a destination that includes a computation die and its corresponding one of the active interposer dies 120A-120C and another one of the active interposer dies 120A-120C that is located one die away. In other words, the packet traverses a single hop to the other one of the active interposer dies 120A-120C. For example, a computation die placed on top of the active interposer die 120C requests data that is stored in the cache(s) 212B of the active interposer die 120B. The communication fabric 210A is not used for this particular type of path 222. However, the communication fabric 210B of the active interposer die 120B is used for each type of the paths 222.

The paths of packets 220-224 are shown illustrating the transfer of packets between computation dies via one or more of the active interposer dies 120A-120C. The path of packets 220 (or path 220) illustrates a path that packets traverse when the packets have a source and a destination that includes a computation die and its corresponding one of the active interposer dies 120A-120C. For example, the path 220 exists for the active interposer die 120B and a computation die (not shown) placed on top of the active interposer die 120B. The path of packets 222 (or path 222) illustrates a path that packets traverse when the packets have a source and a destination that includes a computation die and its corresponding one of the active interposer dies 120A-120C and another one of the active interposer dies 120A-120C that is located one die away. In other words, the packet traverses a single hop to the other one of the active interposer dies 120A-120C. For example, a computation die placed on top of the active interposer die 120C requests data that is stored in the cache(s) 212B of the active interposer die 120B. The communication fabric 210A is not used for this particular type of path 222. However, the communication fabric 210B of the active interposer die 120B is used for each type of the paths 120C.

As described earlier, in various implementations, the active interposer die 120B is from a higher performance bin compared with the active interposer dies 120A and 120C, which are from lower performance bins. The circuitry of the power manager 124 assigns a target power supply voltage on the power rail shared by the active interposer dies 120A-120C. The power manager 124 also assigns a target operating clock frequency to the active interposer die 120A and the active interposer die 120C. Additionally, the power manager 124 assigns a given operating clock frequency that is greater than the target operating clock frequency to the active interposer die 120B. Therefore, the active interposer die 120B provides higher performance than each of the active interposer dies 120A and 120C to alleviate the packet routing congestions in its communication fabric 210B without significantly increasing the power consumption of the integrated circuit 200. It is noted that although the power manager 124 is shown being located in the active interposer die 120B, in other implementations, the power manager 124 is located elsewhere.

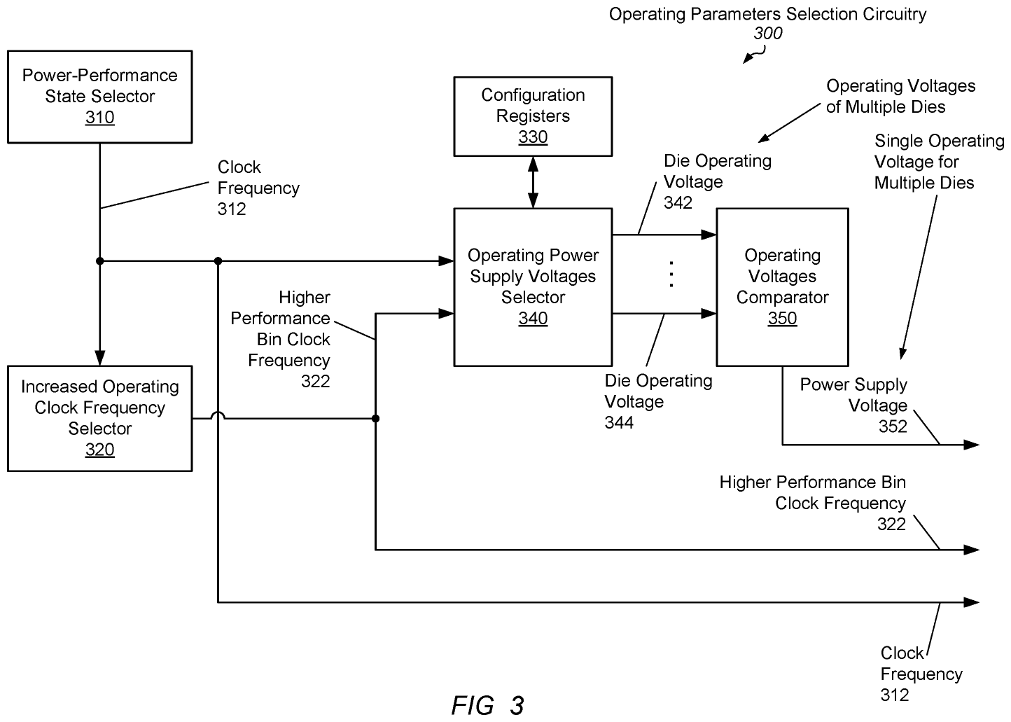

Referring to FIG. 3, a generalized block diagram is shown of an implementation of operating parameters selection circuitry 300. In various implementations, a power manager includes the operating parameters selection circuitry 300 (or circuitry 300). In an implementation, the power manager 124 of the integrated circuit 100 (of FIG. 1) includes the circuitry 300. As shown, the circuitry 300 includes the power-performance state selector 310 (or P-state selector 310), the increased operating clock frequency selector 320 (or selector 320), the configuration registers 330, the operating power supply voltages selector 340 (or selector 340), and the operating voltages comparator 350 (or comparator 350). The circuitry 300 determines a next P-state for an integrated circuit, such as the integrated circuit 100 (of FIG. 1). The circuitry 300 determines a power supply voltage 352 for each of multiple active interposer dies and two operating clock frequencies for the multiple active interposer dies. The higher performance bin clock frequency 322 is sent to at least one active interposer die that is assigned to a higher performance bin, and the clock frequency 312 is sent to other active interposer dies that are not assigned to the higher performance bin. Rather, these other active interposer dies are assigned to lower performance bins. Therefore, the multiple active interposer dies use the power supply voltage 352 that is generated on a shared power rail while at least one of the multiple active interposer dies provides higher performance by using the assigned higher performance bin clock frequency 322.

The P-state selector 310 determines a condition is satisfied to determine a next P-state for an integrated circuit. The condition can include one or more of an indication of a new workload to be executed, a particular time interval has elapsed since a last P-state has been determined, a power limit of the integrated circuit has been updated, the power limit of the integrated circuit has been exceeded, on-die measurements of one or more temperature sensors or current consumption sensors have been updated, and so forth. The P-state selector 310 selects a next operating clock frequency for the integrated circuit such as the clock frequency 312.

The selector 320 receives the clock frequency 312 and determines the higher performance bin clock frequency 322. In various implementations, the integrated circuit includes at least one active interposer die that is assigned to a higher performance bin, whereas other active interposer dies are from other bins that provide lower performance. Therefore, the at least one active interposer die is able to operate at a higher clock frequency than other active interpose dies for a same power supply voltage. In an implementation, circuitry 300 reads one or more of manufacturing information and dynamic (adaptive) voltage and frequency scaling curve data from the multiple active interposer dies and stores this data in the configuration registers 330. The selector 320 accesses this data stored in the configuration registers 330 to obtain the higher performance bin clock frequency 322. In another implementation, the selector 320 sends, to the at least one active interposer die, a request for the higher performance bin clock frequency 322 based on the clock frequency 312.

In an implementation, the selector 340 accesses the data stored in the configuration registers 330 to obtain a power supply voltage supported by the at least one active interposer die for the higher performance bin clock frequency 322. The selector 320 also accesses this data stored in the configuration registers 330 to obtain a power supply voltage supported by each of the other active interposer dies for the clock frequency 312. The selector 340 sends these die operating voltages 342-344 to the comparator 350. In another implementation, the selector 340 sends, to the at least one active interposer die, a request for a supported power supply voltage for the higher performance bin clock frequency 322. The selector 320 also sends, to the other active interposer dies, a request for a supported power supply voltage for the clock frequency 312.

The comparator 350 receives the die operating voltages 342-344 supported by the multiple active interposer dies, and determines the power supply voltage 352. In an implementation, the power supply voltage 352 is a maximum voltage of the die operating voltages 342-344. The circuitry 300 sends the power supply voltage 352 as the next operating power supply voltage of the integrated circuit. Additionally, the circuitry sends the 322 higher performance bin clock frequency 322 to the at least one active interposer die assigned to the higher performance bin as a next operating clock frequency. The circuitry also sends the clock frequency 312 to the other active interposer dies from lower performance bins as a next operating clock frequency.

In another implementation, the operating power supply voltages selector 340 (or selector 340) receives only the clock frequency 312, and determines the die operating voltages 342-344 based on only the clock frequency 312. At the clock frequency 312, the at least one active interposer die assigned to the higher performance bin will have a lower die operating voltage than other active interposer dies from lower performance bins. Therefore, the comparator 350 will determine the power supply voltage 352, which is a maximum voltage of the die operating voltages 342-344, is a die operating voltage of one of the active interposer dies from lower performance bins. At the selected power supply voltage 352, the active interposer dies from lower performance bins will support the clock frequency 312 when executing a workload. However, at the selected power supply voltage 352, the at least one active interposer die from the high-performance bin will support the 322 higher performance bin clock frequency 322 when executing a workload.

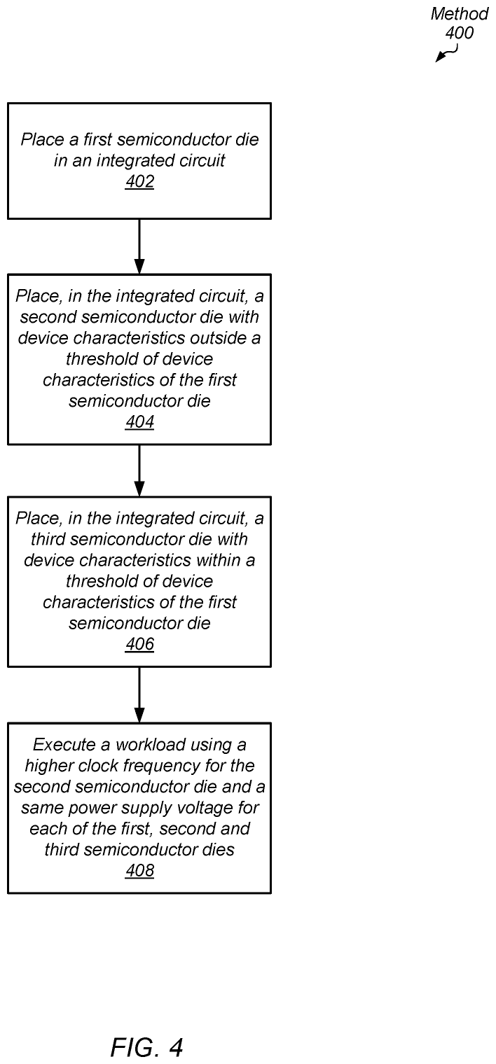

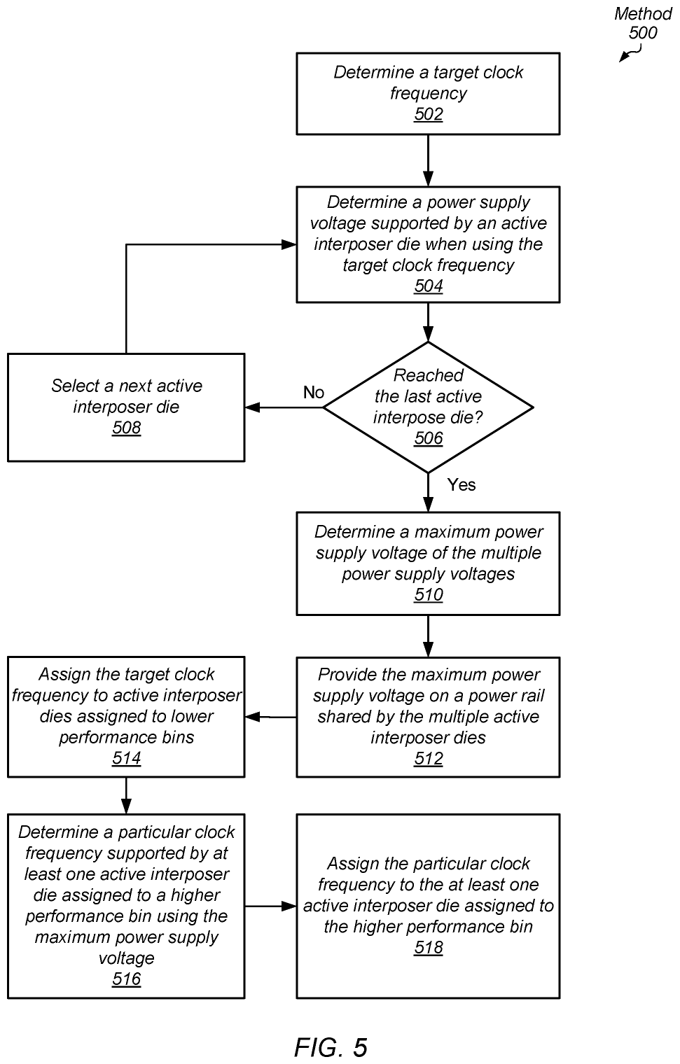

Referring to FIG. 4, a generalized block diagram is shown of a method 400 for efficiently managing performance among replicated semiconductor dies of an integrated circuit despite different circuit behavior of semiconductor dies due to manufacturing variations. For purposes of discussion, the steps in this implementation (as well as in FIG. 5) are shown in sequential order. However, in other implementations some steps occur in a different order than shown, some steps are performed concurrently, some steps are combined with other steps, and some steps are absent.

An integrated circuit being fabricated includes multiple replicated semiconductor dies. In various implementations, the integrated circuit includes multiple active interposer dies. Each of the active interposer dies includes a corresponding communication fabric. For example, the active devices in the active interposer dies implement queues for storing memory access requests, memory access responses, messages, commands, and so forth. These active devices also implement network switches (or routers) of the communication fabric that includes arbitration circuitry, signal drivers, interface circuitry, configuration registers, and so forth. In some implementations, the active devices in the active interposer dies also provide a particular hierarchy of a multi-hierarchical cache memory subsystem, such as a corresponding level three (L3) cache. In some implementations, the integrated circuit is a 3D stacked IC, and each of the active interposer dies has a corresponding computation die placed vertically above it. The multiple active interposer dies are operable to use a same power domain. Therefore, the multiple active interposer dies share a same power rail. During the semiconductor fabrication process, a first semiconductor die, such as a first active interposer die, is placed in the integrated circuit (block 402).

A second semiconductor die with device characteristics outside a threshold of device characteristics of the first semiconductor die is placed in the integrated circuit (block 404). Examples of the device (transistor) characteristics are widths of metal gated and metal traces, doping levels of source and drain regions, thicknesses of insulating oxide layers, thicknesses of metal layers, values of a minimum power supply voltage, values of threshold voltages of n-type transistors and p-type transistors, and so on.

A third semiconductor die with device characteristics within a threshold of device characteristics of the first semiconductor die is placed in the integrated circuit (block 406). In various implementations, the second semiconductor die is physically placed between the first semiconductor die and the third semiconductor die. Being placed between these other dies results in increased data traffic across the second semiconductor die. Given the increased burden on the second semiconductor die, the second semiconductor die is purposely chosen as an active interposer die assigned to a higher performance bin compared to the first and third semiconductor dies, which are active interposer dies from lower performance bins. The second semiconductor die is used as a middle active interposer die with a communication fabric that transfers packets from multiple sources. In such an implementation, the second semiconductor die is purposely placed between the first and second semiconductor dies. These multiple sources include the computation die placed on top of the second semiconductor die as well as the computation dies placed on top of the first semiconductor die and the third semiconductor die. Therefore, the second functional block has higher packet routing congestion in its communication fabric compared to the communication fabrics of the first functional block and the third functional block. The fabricated integrated circuit executes a workload using a higher clock frequency for the second semiconductor die and a same power supply voltage for each of the first, second and third semiconductor dies (block 408).

Turning now to FIG. 5, a generalized block diagram is shown of a method 500 for efficiently managing performance among replicated semiconductor dies of an integrated circuit despite different circuit behavior of semiconductor dies due to manufacturing variations. An integrated circuit being fabricated includes multiple replicated semiconductor dies. In various implementations, the integrated circuit includes multiple active interposer dies. The multiple active interposer dies are operable to use a same power domain. Therefore, the multiple active interposer dies share a same power rail. The multiple active interposer dies are from different performance bins. The integrated circuit determines a target clock frequency (block 502). In an implementation, a power manager of the integrated circuit updates operating parameters such as determining a next P-state.

The integrated circuit determines a power supply voltage supported by an active interposer die when using the target clock frequency (block 504). In some implementations, the power manager of the integrated circuit accesses one or more of manufacturing information and dynamic (adaptive) voltage and frequency scaling curve data of the active interposer die. In an implementation, the active interposer die stores this information in a fuse ROM. If the power manager has not yet reached the last active interposer die (“no” branch of the conditional block 506), then the power manager selects a next active interposer die (block 508). Afterward, control flow of method 500 returns to block 504 where the power manager of the integrated circuit determines a power supply voltage supported by the next selected active interposer die when using the target clock frequency.

If the power manager has reached the last active interposer die (“yes” branch of the conditional block 506), then the power manager determines a maximum power supply voltage of the multiple power supply voltages (block 510). The power manager provides the maximum power supply voltage on a power rail shared by the multiple active interposer dies (block 512). The power manager assigns the target clock frequency to active interposer dies from lower performance bins (block 514). The power manager determines a particular clock frequency supported by at least one active interposer die assigned to a higher performance bin using the maximum power supply voltage (block 516). The particular clock frequency is greater than the target clock frequency. In some implementations, the particular clock frequency is a maximum clock frequency that the at least one active interposer die is capable of using when also using the maximum power supply voltage. The power manager assigns the particular clock frequency to the at least one active interposer die assigned to the higher performance bin (block 518). Therefore, the at least one active interposer die assigned to the higher performance bin provides higher performance to alleviate packet routing congestions in its communication fabric without significantly increasing the power consumption of the integrated circuit.

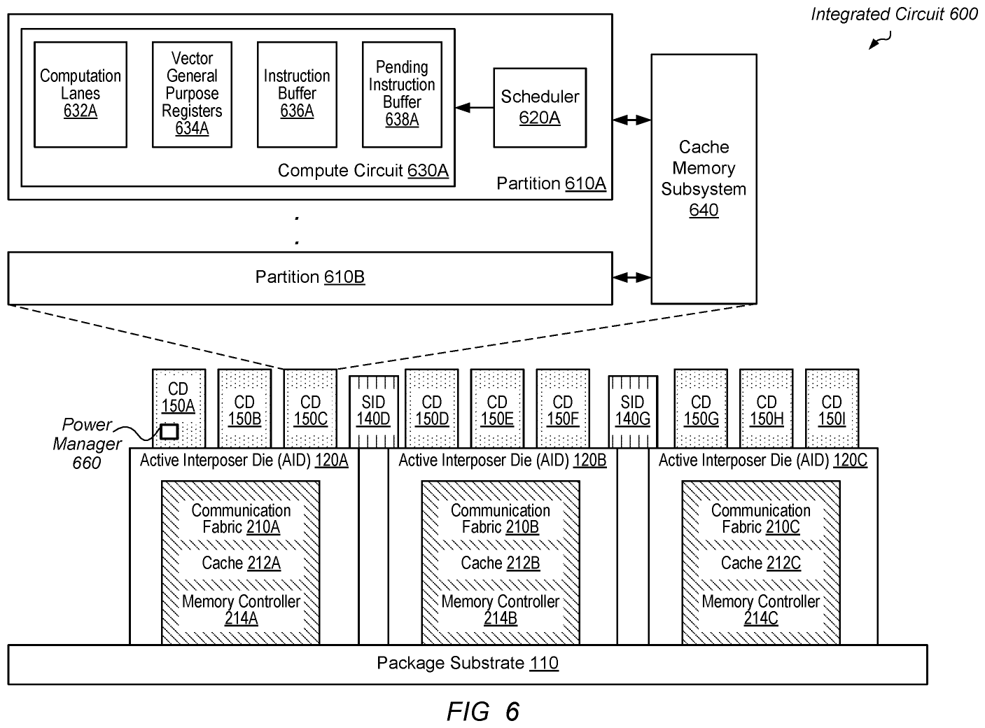

Turning now to FIG. 6, a generalized block diagram is shown of an implementation of an integrated circuit 600. In various implementations, the integrated circuit 600 is a three-dimensional (3D) stacked integrated circuit (IC). Circuitry and blocks described earlier are numbered identically. Each of the computation dies (CDs) 150A-150I is on top of a corresponding one of the active interposer dies (AIDs) 120A-120C, and includes at least two partitions. In the illustrated implementation, the computation die 150C includes the partitions 610A-610B and the cache memory subsystem 640. Although two partitions are shown, each of the computation dies 150A-150I with the same instantiated circuitry can have any number of partitions based on design requirements. In various implementations, the partition 610B of the computation die 150C is an instantiated copy of the circuitry of the partition 610A.

As shown, the partition 610A of the computation die 150C includes a scheduler 620A and compute circuit 630A. The compute circuit 630A includes circuitry that performs (or “executes”) tasks (e.g., based on execution of instructions, detection of signals, movement of data, generation of signals and/or data, and so on). In various implementations, the compute circuit 630A is a single instruction multiple data (SIMD) circuit. The circuitry of the computation lanes 632A process highly parallel data applications. The computation lanes 632A includes multiple lanes with each lane being an instantiation of the same circuitry that is capable of executing a thread. In some implementations, these multiple lanes within the computation lanes 632A operate in lockstep. In various implementations, the data flow within each of these multiple lanes is pipelined. Pipeline registers are used for storing intermediate results and circuitry for arithmetic logic units (ALUs) perform integer arithmetic, floating-point arithmetic, Boolean logic operations, branch condition comparisons and so forth. These components are not shown for ease of illustration.

The circuitry within a given row across the multiple lanes of the computation lanes 632A includes the same circuitry and operates on a same instruction, but different data associated with a different thread. Each data item is processed independently of other data items, but the same sequence of operations of the subroutine is used. In an implementation, the circuitry of the computation lanes 632A is a SIMD circuit that includes 64 lanes of execution. In such an implementation, the computation lanes 632A are able to simultaneously process 64 threads. In other implementations, the circuitry of the computation lanes 632A is a SIMD circuit that includes another number lanes of execution based on design requirements. By being an instantiated copy of the computation lanes 632A, the computation lanes of a compute circuit of the partition 610B are implemented in a similar manner.

The tasks assigned to the compute circuit 630A are grouped into work blocks. As used herein, a “work block” is a block of work executed in an atomic manner. In some implementations, the granularity of the work block includes a single instruction of a computer program, and this single instruction can also be divided into two or more micro-operations (micro-ops) by the apparatus 100. In other implementations, the granularity of the work block includes one or more instructions of a subroutine. A particular combination of the same instruction and a particular data item of multiple data items is referred to as a “work item.” A work item is also referred to as a thread. A number of multiple work items are grouped into a “wavefront” for simultaneous execution by multiple SIMD execution lanes of a corresponding one of the computation lanes 632A. In such implementations, the work block is a “wavefront.”

In an implementation, an external scheduler (not shown), such as a command processor or other circuit, receives work blocks for execution on the computation lanes 632A, and sends the assigned work blocks to the scheduler 620A of the partition 610A. This external scheduler performs these assignments based on load balancing, a round-robin scheme, or another scheme. In one implementation, work blocks are wavefronts, and this scheduler retrieves the wavefronts from a buffer such as system memory. As the computation dies 150A-150I execute instructions of the assigned work blocks, the computation dies 150A-150I generate memory access requests, messages, commands, and so forth, which are assembled into packets. These packets are sent to destinations across the integrated circuit 600 via the active interposer dies 120A-120C.

As described earlier, the packet routing of the active interposer die 120B becomes congested prior to any congestion of the active interposer die 120A and the active interposer die 120C. This packet routing congestion is caused by the topology of the integrated circuit 200 that includes the active interposer die 120B physically located between the active interposer die 120A and the active interposer die 120C. However, the active interposer die 120B is from a higher performance bin compared with the active interposer dies 120A and 120C, which are from lower performance bins. In various implementations, the power manager 660 has the same functionality as the power manager 124 (of FIG. 1). Therefore, the circuitry of the power manager 660 assigns a target power supply voltage on the power rail shared by the active interposer dies 120A-120C. The power manager 660 also assigns a target operating clock frequency to the active interposer die 120A and the active interposer die 120C. Additionally, the power manager 660 assigns a given operating clock frequency that is greater than the target operating clock frequency to the active interposer die 120B. Therefore, the active interposer die 120B provides higher performance than each of the active interposer dies 120A and 120C to alleviate the packet routing congestions in its communication fabric 210B without significantly increasing the power consumption of the integrated circuit 600.

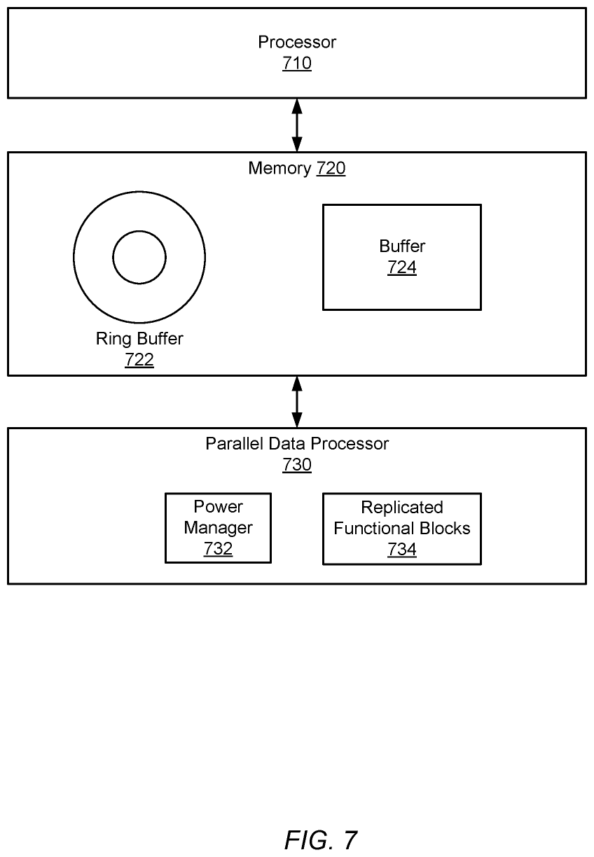

Turning now to FIG. 7, a generalized block diagram is shown of a computing system 700 that efficiently manages performance and power consumption among replicated functional blocks of an integrated circuit despite different circuit behavior of semiconductor dies due to manufacturing variations. As shown, the computing system 700 includes a processor 710, a memory 720 and a parallel data processor 730. In some implementations, the functionality of the computing system 700 is included as components on a single die, such as a single integrated circuit. In other implementations, the functionality of the computing system 700 is included as multiple dies on a system-on-a-chip (SOC). In other implementations, the functionality of the computing system 700 is implemented by multiple, separate dies that have been fabricated on separate silicon wafers and placed in system packaging known as multi-chip modules (MCMs). In various implementations, the computing system 700 is used in a desktop, a portable computer, a mobile device, a server, a peripheral device, or other.

The circuitry of the processor 710 processes instructions of a predetermined algorithm. The processing includes fetching instructions and data, decoding instructions, executing instructions, and storing results. In one implementation, the processor 710 uses one or more processor cores with circuitry for executing instructions according to a predefined general-purpose instruction set architecture (ISA). In various implementations, the processor 710 is a general-purpose central processor (CPU). The parallel data processor 730 uses one or more processor cores with a relatively wide single instruction multiple data (SIMD) micro-architecture to achieve high throughput in highly data parallel applications. In an implementation, the parallel data processor 730 is a graphics processing unit (GPU). In other implementations, the parallel data processor 730 is another type of processor. In an implementation, the parallel data processor 730 stores results data in the buffer 724 of the memory 720.

In various implementations, the functional blocks 734 are active interposer dies placed on a package substrate. Each of the active interposer dies has one or more computation dies placed on top of it. In an implementation, each computation die includes one or more SIMD circuits with the circuitry of multiple lanes of execution. The power manager 732 selects operating parameters for the functional blocks 734 in a manner to manage performance and power consumption among the replicated functional blocks 734 despite different circuit behavior of the functional blocks 734 due to manufacturing variations. In various implementations, the power manager 732 includes the functionality of the power manager 124 (of FIG. 1) and the operating parameters selection circuitry 200 (of FIG. 2). The parallel data processor 730 is efficient for data parallel computing found within loops of applications, such as in applications for manipulating, rendering, and displaying computer graphics. In such cases, each of the data items of a wave front is a pixel of an image. The applications can also include molecular dynamics simulations, finance computations, neural network training, and so forth. The highly parallel structure of the parallel data processor 730 makes it more effective than the general-purpose structure of the processor 710.

In various implementations, threads are scheduled on one of the processor 710 and the parallel data processor 730 in a manner that each thread has the highest instruction throughput based at least in part on the runtime hardware resources of the processor 710 and the parallel data processor 730. In some implementations, some threads are associated with general-purpose algorithms, which are scheduled on the processor 710, while other threads are associated with parallel data computationally intensive algorithms such as video graphics rendering algorithms, which are scheduled on the parallel data processor 730. The functional block 734 can be used for real-time data processing such as rendering multiple pixels, image blending, pixel shading, vertex shading, and geometry shading. Some threads, which are not video graphics rendering algorithms, still exhibit parallel data and intensive throughput. These threads have instructions which are capable of operating simultaneously with a relatively high number of different data elements (or data items). Examples of these threads are threads for scientific, medical, finance and encryption/decryption computations.

To change the scheduling of the above computations from the processor 710 to the parallel data processor 730, software development kits (SDKs) and application programming interfaces (APIs) were developed for use with widely available high-level languages to provide supported function calls. The function calls provide an abstraction layer of the parallel implementation details of the parallel data processor 730. The details are hardware specific to the parallel data processor 730 but hidden to the developer to allow for more flexible writing of software applications. The function calls in high level languages, such as C, C++, FORTRAN, and Java and so on, are translated to commands which are later processed by the hardware in the parallel data processor 730. Although a network interface is not shown, in some implementations, the parallel data processor 730 is used by remote programmers in a cloud computing environment.

A software application begins execution on the processor 710. Function calls within the application are translated to commands by a given API. The processor 710 sends the translated commands to the memory 720 for storage in the ring buffer 722. The commands are placed in groups referred to as command groups. In some implementations, the processors 710 and 730 use a producer-consumer relationship, which is also be referred to as a client-server relationship. The processor 710 writes commands into the ring buffer 722. Circuitry of a controller (not shown) of the parallel data processor 730 reads the commands from the ring buffer 722. In some implementations, the controller is a command processor of a GPU. The functional blocks 734 process the commands (instructions) of the assigned work blocks, and writes result data to the ring buffer 722.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R, CD-RW, DVD-R, DVD-RW, or Blu-Ray. Storage media further includes volatile or non-volatile memory media such as RAM (e.g., synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g., Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high-level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware-based type emulator from such vendors as Cadence®, EVE®, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An integrated circuit comprising:
circuitry configured to update operating parameters of a plurality of functional blocks including:
a given power supply voltage assigned to each of a first functional block, second functional block and third functional block;
a target clock frequency assigned to the first functional block and the third functional block; and
a given clock frequency, greater than the target clock frequency, assigned to the second functional block; and
execute, by the plurality of functional blocks, a workload using the operating parameters.

2. The integrated circuit as recited in claim 1, wherein the second functional block is assigned to a higher performance bin, based on manufacturing variations, than the first functional block and the third functional block.

3. The integrated circuit as recited in claim 2, wherein the circuitry is further configured to determine a plurality of power supply voltages, each being a power supply voltage supported by a separate one of the plurality of functional blocks when using the target clock frequency.

4. The integrated circuit as recited in claim 3, wherein the given power supply voltage is a maximum power supply voltage of the plurality of power supply voltages.

5. The integrated circuit as recited in claim 1, wherein the second functional block is assigned a higher clock frequency than that of the first functional block and the third functional block, based at least in part on a physical position of the second functional block relative to the first functional block and third functional block.

6. The integrated circuit as recited in claim 2, wherein each of the plurality of functional blocks is an active interposer die comprising a communication fabric.

7. The integrated circuit as recited in claim 6, wherein the second functional block routes packets between sources and destinations that include at least the first functional block and the third functional block.

8. A method comprising:
updating, by circuitry, operating parameters of a plurality of functional blocks of an integrated circuit, the functional blocks representing instantiated copies of integrated circuitry including:
a given power supply voltage assigned to each of a first functional block, second functional block, and third functional block;
a target clock frequency assigned to the first functional block and the third functional block; and
a given clock frequency, greater than the target clock frequency, assigned to the second functional block; and
executing, by the plurality of functional blocks, a workload.

9. The method as recited in claim 8, wherein the second functional block is assigned to a higher performance bin, based on manufacturing variations, than the first functional block and the third functional block.

10. The method as recited in claim 9, further comprising providing, by the circuitry, a plurality of power supply voltages, each being a corresponding power supply voltage supported by a separate one of the plurality of functional blocks when using the target clock frequency.

11. The method as recited in claim 10, wherein the given power supply voltage is a maximum power supply voltage of the plurality of power supply voltages.

12. The method as recited in claim 8, further comprising assigning the second functional block a higher clock frequency than that of the first functional block and the third functional block, based at least in part on a physical position of the second functional block relative to the first functional block and third functional block.

13. The method as recited in claim 9, wherein each of the plurality of functional blocks is an active interposer die comprising a communication fabric.

14. The method as recited in claim 13, further comprising routing packets, by the second functional block, between sources and destinations that include at least the first functional block and the third functional block.

15. A computing system comprising:
a power manager circuit;
a first processor comprising a plurality of semiconductor dies, each representing an instantiated copy of integrated circuitry configured to process a workload; and
a second processor comprising integrated circuitry configured to assign a workload to the first processor; and
wherein the power manager circuit is configured to:
set a target clock frequency for at least a first semiconductor die, a second semiconductor die, and a third semiconductor die of the plurality of semiconductor dies;
select a given power supply voltage for each of the first semiconductor die, the second semiconductor die, and the third semiconductor die; and
update operating parameters of the plurality of semiconductor dies to include:
the given power supply voltage assigned to each of the first semiconductor die, the second semiconductor die, and the third semiconductor die;
the target clock frequency assigned to the first semiconductor die and the third semiconductor die; and
a given clock frequency greater than the target clock frequency assigned to the second semiconductor die.

16. The computing system as recited in claim 15, wherein:
each of the first semiconductor die and the third semiconductor die is assigned to a first performance bin; and
the second semiconductor die is assigned to a second performance bin that includes semiconductor dies that provide higher performance than semiconductor dies assigned to the first performance bin due to semiconductor manufacturing variations.

17. The computing system as recited in claim 16, wherein the power manager circuit is further configured to determine a plurality of power supply voltages, each being a corresponding power supply voltage supported by a separate one of the plurality of semiconductor dies when using the target clock frequency.

18. The computing system as recited in claim 17, wherein the power manager circuit is further configured to determine the given power supply voltage is a maximum power supply voltage of the plurality of power supply voltages.

19. The computing system as recited in claim 18, wherein the power manager circuit is further configured to determine the given clock frequency as an operating clock frequency that the second semiconductor die is configured to use when using the given power supply voltage.

20. The computing system as recited in claim 16, wherein each of the plurality of semiconductor dies is an active interposer die comprising a communication fabric.
